(19) United States
(12) Patent Application Publication
(10) Pub. No.: US 2025/0283411 A1
(43) Pub. Date: Sep. 11, 2025

(54) Optimization Framework for Multi-Stage Compressor Disk Design in Gas Turbine Engine

(71) Applicant: VIETTEL GROUP, Ha Noi City (VN)

(72) Inventors: NHAT MINH HOANG, Ha Noi City (VN); MINH DUC HA, Ha Noi City (VN); TIEN QUYET NGUYEN, Ha Noi City (VN); VAN AN LE, Ha Noi City (VN)

(73) Assignee: VIETTEL GROUP, Ha Noi City (VN)

(21) Appl. No.: 19/009,003

(22) Filed: Jan. 3, 2025

(30) Foreign Application Priority Data
Mar. 8, 2024 (VN) 1-2024-01743

(51) Int. Cl. F01D 5/14; G06F 30/17

(52) U.S. Cl. CPC F01D 5/141; G06F 30/17; F05D 2220/32; F05D 2240/30; F05D 2250/20

(57) ABSTRACT

A systematic framework for optimizing multi-stage axial compressor disk designs in gas turbine engines. By combining finite element analysis (FEA), Design of Experiments (DOE), and optimization algorithms of multi-objective genetic algorithm (MOGA), the method balances stress, deformation, and mass to enhance structural performance. The six-step process includes blade modeling, parameterizing disk geometry, structural analysis using FEA, developing functional relationships, applying optimization algorithms, and generating manufacturable 3D disk models. This approach reduces weight, improves fuel efficiency, and adapts to various compressor designs and materials, enhancing the overall performance of gas turbine engines.

### TECHNICAL DISCIPLINE SPECIFICATION

This invention pertains to the field of gas turbine engine design, focusing on the structural optimization of multi-stage axial compressor disks. It is particularly significant in improving the performance and efficiency of gas turbines across applications in aviation, maritime propulsion, and energy generation.

Compared to traditional methods, which often rely on analytical calculations or simplified geometries, this invention utilizes cutting-edge computational techniques and high-performance computing to achieve unprecedented precision and efficiency. By integrating finite element analysis (FEA), multi-objective genetic algorithms (MOGA), and the Design of Experiments (DOE) framework, the approach allows for the detailed evaluation of complex compressor disk geometries under realistic operating conditions, including temperature, pressure, and rotational dynamics. Existing solutions frequently face challenges such as computational inefficiency, an inability to handle intricate boundary conditions, or oversimplified models that compromise accuracy. This invention addresses these gaps by streamlining the entire optimization process—from parameterization to analysis and design-into an automated, highly accurate, and time-efficient framework. Its innovative use of advanced algorithms and computational power significantly reduces the manual effort required and enhances design flexibility.

By focusing on weight reduction and structural reliability, this framework not only enhances fuel efficiency and reduces emissions but also adapts seamlessly to varying compressor designs and materials. This makes it a versatile, precise, and convenient solution that meets the rigorous demands of modern gas turbine engines while pushing the boundaries of current engineering practices.

### TECHNICAL STATUS OF THE INVENTION

In aviation, enhancing design efficiency and optimizing fuel consumption remain critical priorities. Beyond selecting high-strength, low-density materials, geometric structural optimization plays a key role in reducing the weight of flight systems. For gas turbine engines, which must deliver high thrust and fuel efficiency, the compressor a crucial component responsible for converting airflow energy and accounting for over 60% of the engine's efficiency-requires highly meticulous design and optimization. The compressor structure is classified as Class I in the engine design process due to its fundamental importance.

Operating under extreme rotational speeds, pressures, and temperatures, compressors endure complex force interactions. These conditions demand materials with exceptional mechanical and thermal properties, such as titanium or nickel-based superalloys. Lightweight alternatives like composites and aluminum lack the necessary strength and thermal resilience for these harsh environments. However, the high density of traditional materials increases compressor mass, intensifying rotational loads and dynamic instability. Excess mass amplifies centrifugal forces, which can lead to material fatigue, vibration, and long-term structural degradation. Furthermore, elevated operating temperatures cause significant thermal expansion and stress, potentially compromising dimensional tolerances and leading to inefficiencies or failures.

Geometric optimization directly addresses these challenges by minimizing material usage without sacrificing structural integrity. For example, advanced optimization techniques allow for the precise redistribution of material to strengthen critical load-bearing regions while reducing weight in non-critical areas. This not only mitigates the effects of rotational inertia but also enhances dynamic stability, reducing vibration and improving overall reliability. Moreover, refined designs can better accommodate thermal stresses by ensuring uniform heat distribution and minimizing localized stress concentrations, significantly extending the component's lifespan and operational safety margins.

Historically, axial compressor disk design relied on analytical methods and integral equations. For example, NASA's 1995 rotor disk optimization methodology, while innovative, was computationally intensive and struggled to accommodate intricate geometries. The introduction of the finite element method (FEM) revolutionized structural analysis by enabling faster and more accurate evaluations of complex structures. Despite these advances, many FEM-based studies have oversimplified the geometries of multi-stage compressors or excluded critical aerodynamic boundary conditions, such as temperature and pressure gradients.

Although computational techniques have advanced, current methods for compressor geometric optimization still face limitations. Simplifications and inaccuracies, particularly in accounting for stress, mass, deformation, and real-world operating conditions, constrain their effectiveness. Overcoming these challenges is essential for advancing the design of multi-stage axial compressors and meeting the rigorous performance and efficiency demands of modern gas turbine engines.

### Technical Principle of the Invention

This invention presents a method for optimizing the structural design of multi-stage axial compressor disks for jet engines, employing the finite element method and a multi-objective optimization algorithm based on the design of experiments (DOE). By systematically adjusting the geometric dimensions of the compressor disk, FEM is used to analyze and predict stress, deformation, and mass, forming the basis for constructing objective functions. These objective functions are optimized within constraints defined by the material properties, focusing on minimizing mass while maintaining structural reliability under operating conditions. This innovative approach bridges the gap between computational efficiency and design complexity, overcoming limitations of traditional methods that relied on simplified geometry or extensive computational time. The integration of FEM and DOE enables precise material distribution and enhanced structural performance, reducing weight while ensuring durability. Such advancements are critical for modern gas turbine engines, where reduced mass contributes to improved fuel efficiency, reduced emissions, and lower operational costs. Moreover, this method can be adapted to various compressor designs and materials, making it versatile for future propulsion technologies.

In order to achieve the above goal, the proposed design method includes the following six (06) steps:
Step 1: Blade modeling—create a 3D model of the blade based on aerodynamic results. The blade model includes the size parameters of the inner diameter, outer diameter, and axial length of the compressor.
Step 2: Parameterizing disk geometric dimensions—From the 3D blade model, construct the initial 3D model of the compressor disk. Parameterize the basic dimensions of the disk (disk bore radius, disk bore thickness, disk bore height, etc.).
Step 3: Calculating compressor structural behavior with changing geometric parameters—Build the computational model with initial boundary conditions (temperature, pressure, rotational speed, etc.). Perform structural behavior calculations of the compressor as the disk dimension parameters change.
Step 4: Functionally relating parameters with calculation results—construct functions to analyze the impact of dimensional parameters on the compressor's structural behavior (stress, displacement).
Step 5: Selecting dimensions using optimization algorithm—Use multi-objective genetic algorithm (MOGA) optimization functions to select the optimal dimensions of the compressor disk.
Step 6: Outputting the 3D geometric results of the compressor disk—The final geometric result is selected from the parameter set in Step 5 and recalculated to check the convergence of the initial stress calculations.

### BRIEF DESCRIPTION OF THE DRAWINGS

FIG. 1 describes the flowchart illustrating the optimization process of multi-stage axial compressor disk design;

FIG. 2 describes the configuration of the blade from aerodynamic design;

FIG. 3 describes the geometric structure of the disk and the parameterization of its dimensions;

FIG. 4 describes FEM structural analysis results showcasing stress, and DOE constraint;

FIG. 5 describes the configuration of the optimized compressor;

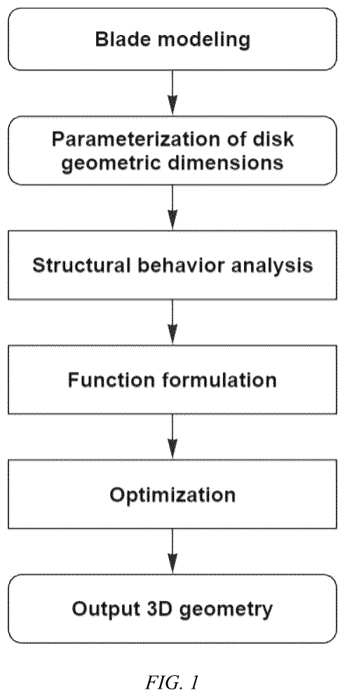

### DETAILED DESCRIPTION OF THE INVENTION

The proposed approach consists of the following steps: Step 1: model the wing leaf; step 2: parameterize the disk geometry; step 3: perform calculations while changing geometric parameters; step 4: function digitizes parameters with calculation results; step 5: selecting size using an optimization approach. Step 6: Export the compressor disk's 3D geometry findings. The steps for implementing the invention are as follows:

### 1^{st} Step: Blade Modeling

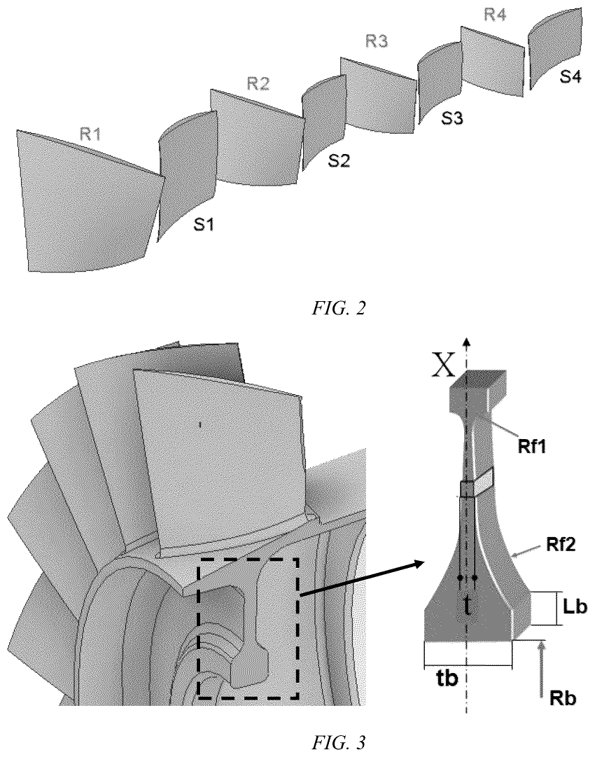

Create a 3D model of the blade using computer-aided engineering (CAE) software. The aerodynamic design process ensures the blades meet initial efficiency requirements (referring to FIG. 2), serving as input for the compressor disk design. The blade also establishes critical boundary conditions, such as temperature and aerodynamic pressure, across each stage. The compressor disk, which houses and supports the blades, plays a critical role in ensuring structural continuity, connecting to the engine's rotating shaft, and balancing aerodynamic and centrifugal forces.

Key dimensions derived from the blade design include:
Disk rim diameter: The difference between the blade tip diameter and blade height.
Disk rim width: The minimum space required for blade placement on the disk.
Interstage distance: The minimum gap for arranging static guide vanes between compressor stages.

### 2^{nd} Step: Parameterizing the Geometric Dimensions of the Disk

The compressor disk is divided into three distinct structural parts: the disk rim, the disk web, and the disk bore. The disk rim, which houses the blades, typically has the greatest thickness; the disk web is the thinnest part, serving as a connecting element on the disk; and the disk bore balances the centrifugal forces exerted by the blades. The disk rim dimensions are defined by the blades with the corresponding compression stage (the minimum distance for arranging blades on the disk). The disk bore significantly impacts stress and deformation on the disk.

Referring to FIG. 3, parameterize the geometric dimensions of the compressor disk including:
Disk rim fillet radius: Rf1
Disk web thickness: t
Disk bore fillet radius: Rf2
Disk bore thickness: tb
Disk bore height: Lb
Disk bore radius: Rb

These dimensions significantly influence the stress distribution, deformation, and mass of the disk under operational conditions.

3^{rd} Step: Calculating Compressor Structural Behavior with Changing Geometric Parameters

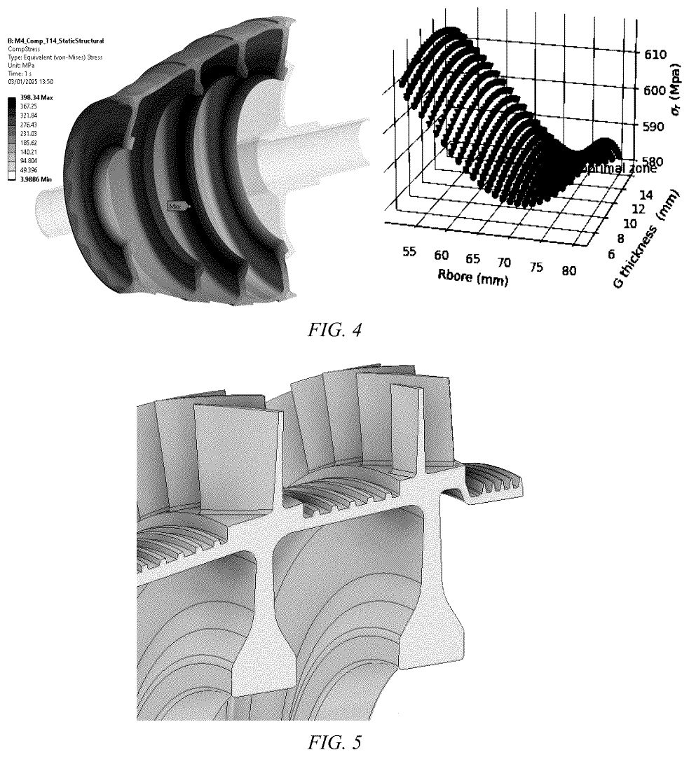

Use the FEM to calculate the compressor structure under engine operating conditions. The operating conditions of the engine at design rotational speed serve as input parameters, including: blade surface temperature and pressure, design rotational speed, which directly affect stress and deformation of the compressor structure. The FEM outputs the stress, deformation, and mass of the compressor corresponding to each set of geometric parameters (refer to FIG. 4).

4^{th} Step: Functionally Relating Parameters with Calculation Results

From the FEA results, construct functional equations relating three quantities from the calculated results, including stress, deformation, and mass to all the calculated geometric parameters. The constructed functions have the form:
Stress: σ=f (Rf1, t, Rf2, tb, Lb, Rb).
Deformation: ¿=f (Rf1, t, Rf2, tb, Lb, Rb)
Mass: m=f (Rf1, t, Rf2, tb, Lb, Rb)

These functions establish a quantitative relationship between design variables and structural performance metrics.

### 5^{th} Step: Selecting Disk Dimensions Using an Optimization Algorithm

Develop constraint equations based on the three equations of stress, deformation, and mass provided in Step 4. The constraint conditions are based on the design material limits and compressor design requirements and the mass objective function:
Stress: σ≤σph/n, where σph is the design material's failure stress. The value of n is the safety factor, typically ranging from 1.2 to 1.5 for gas turbine engines and can vary depending on specific standards and engine applications.
Deformation: εr≤G, where G is the design clearance between the blade tip and the engine casing. For small jet engines, G typically ranges from 0.4 to 1 mm, depending on design requirements.
Mass m is the objective function to be minimized.

Thus, the optimization algorithm MOGA will select the set of dimensional parameters that satisfy the design conditions for stress, deformation, and have the minimum mass.

### 6^{th} Step: Outputting the 3D Geometric Results of the Compressor Disk

From the set of dimensional parameters derived from the algorithm, construct the 3D geometry of the compressor (referring to FIG. 5). The feasibility of manufacturing the optimized compressor configuration must be evaluated. In some cases, the disk bore thickness might be too large and the disk web too thin, hindering the milling process if using CNC milling methods.

1. A method for optimizing a design of a multi-stage axial compressor disk structures includes the following steps:
step 1: blade modeling: Constructing a 3D model of a blade using computer-aided design software; blades of the multi-stage axial compressor are designed through an aerodynamic design process, ensuring initial design efficiency as an input condition for calculating and selecting a compressor disk, the compressor disk, located below a blade structure, ensures structural continuity and connects the compressor to an engine's rotating shaft, additionally, the compressor disk balances forces caused by aerodynamic effects and centrifugal forces from the blades;
the blade designed from the aerodynamic design process defines limiting dimensions of the compressor disk, including: a disk rim diameter (a difference between blade tip diameter and blade height), a disk rim width where the blades are housed (a minimum distance for arranging blades on the disk), and a distance between compressor stages (a minimum distance for arranging the static guide vanes), the blade also serves as a point for setting boundary conditions of temperature and aerodynamic pressure across each compressor stage;
step 2: parameterizing disk geometric dimensions: the compressor disk is divided into three distinct structural parts: a disk rim, a disk web, and a disk bore, parameterizing its geometry using the following variables:
disk rim fillet radius: Rf1
disk web thickness: t
disk bore fillet radius: Rf2
disk bore thickness: tb
disk bore height: Lb
disk bore radius: Rb
step 3: calculating compressor structural behavior with changing geometric parameters: using finite element analysis (FEA) software to calculate structural behavior under engine operating conditions, wherein:
input parameters include blade surface temperature, aerodynamic pressure, and design rotational speed;
outputs include stress, deformation, and mass for varying geometric parameters;
step 4: functionally relating parameters with calculation results: from the FEA results, constructing functional equations relating three quantities from the calculated results, including stress, deformation, and mass to all calculated geometric parameters, the constructed functional equations have the form:
stress: σ=f (Rf1, t, Rf2, tb, Lb, Rb)
deformation: ¿=f (Rf1, t, Rf2, tb, Lb, Rb)
mass: m=f (Rf1, t, Rf2, tb, Lb, Rb)
step 5: selecting disk dimensions using an optimization algorithm: developing constraint equations based on the three equations of stress, deformation, and mass provided in Step 4, the constraint conditions are based on design material limits and compressor design requirements and a mass objective function:
stress: σ≤σph/n, where σph is the design material's failure stress, the value of n is a safety factor, typically ranging from 1.2 to 1.5 for gas turbine engines and can vary depending on specific standards and engine applications;
deformation: εr≤G, where G is a design clearance between a blade tip and an engine casing, for small jet engines, G typically ranges from 0.4 to 1 mm, depending on design requirements;
mass m is the objective function to be minimized;
an optimization algorithm MOGA will select a set of geometric parameters that satisfy design conditions for stress, deformation, and have a minimum possible mass;
step 6: outputting 3D geometric results of the compressor disk: generating an optimized 3D geometry of the compressor disk based on selected parameters, wherein:
the design is validated for manufacturability, ensuring compatibility with CNC milling or equivalent methods;
adjustments may be made to balance manufacturability and structural integrity in cases where bore thickness or web dimensions pose challenges.
